(19) United States
(12) Patent Application Publication
(10) Pub. No.: US 2005/0059247 A1
(43) Pub. Date: Mar. 17, 2005

(54) Method for manufacturing SiC substrate

(75) Inventor: Naoyuki Ikenaka, Saijo-shi (JP)

Correspondence Address: MERCHANT & GOULD PC, P.O. BOX 2903, MINNEAPOLIS, MN, 55402-0903, US

(73) Assignee: Matsushita Electric Industrial Co., Ltd., Kadoma-shi (JP)

(21) Appl. No.: 10/942,706

(22) Filed: Sep. 15, 2004

(30) Foreign Application Priority Data
Sep. 16, 2003 (JP) 2003-323594

(51) Int. Cl. H01L 21/00; H01L 21/302; H01L 21/461

(52) U.S. Cl. 438/692; 438/105

(57) ABSTRACT

A method for manufacturing a SiC substrate includes a polishing step of polishing the surface of a plate-shaped SiC material by moving a polishing pad, obtained by applying an abrasive to a pad, relative to the surface of the SiC material in a state where the polishing pad is in contact with the SiC material, and the abrasive contains colloidal silica and a dispersion medium in which the colloidal silica is dispersed and the abrasive has a pH of 4 to 9. Thus, it is possible to suppress processing damage and cracks while alleviating the burden on a polishing apparatus or on the environment. Consequently, a SiC substrate with a small surface roughness and high reliability can be manufactured.

### BACKGROUND OF THE INVENTION

1. Field of the Invention

The present invention relates to a method for manufacturing a SiC substrate.

2. Related Background Art

Power devices (electronic devices) that have reduced losses of electric energy and have achieved a high performance directly contribute to a significant reduction in electric power consumption, so that they have been used in various fields. Currently, power devices that employ silicon substrates are used. However, due to the material characteristics of silicon, there is a limit to a further increase in performance of power devices by subjecting silicon to fine processing. In particular, silicon cannot be used under such conditions as high temperatures, so that there is a need for a material to replace silicon.

An example of a material to replace silicon is SiC (silicon carbide). The width of the forbidden band of SiC is three times wider than the width of the forbidden band of silicon, so that SiC can be used at a higher temperature than silicon. The dielectric strength of SiC is about ten times greater than that of silicon. Therefore, with SiC substrates, power devices can be made smaller than in the case where silicon substrates are used. Moreover, the thermal conductivity of SiC is about three times higher than that of silicon. That is, SiC also has the advantage that it is superior to silicon in heat dissipation and easier to cool than silicon. As described above, SiC has superior characteristics compared to silicon,and thus SiC substrates have received attention as semiconductor substrates for power devices to replace silicon substrates.

However, SiC substrates that are used for power devices are required to have a small surface roughness. As an abrasive that is used to polish a plate-shaped SiC material to obtain a SiC substrate, diamond abrasive grains or a suspension (pH 10 to 15) that contains SiO₂ (colloidal silica) is used (for example, see JP H7-288243 A).

However, when diamond abrasive grains were used as an abrasive, polishing was performed at a high speed, but there was the problem of processing damage and cracks due to chipping. When a suspension (pH 10 to 15) containing SiO₂ (colloidal silica) was used, the above-mentioned processing damage and cracks did not occur, but there was the problem that the suspension caused considerable damage to a polishing device and also placed a significant burden on the environment because the suspension is a strong alkali. Moreover, the surface roughness of the obtained SiC substrate was not sufficiently small, and thus there has been a demand for SiC substrates having an even smaller surface roughness (for example, the surface roughness is 0.5 nm or less).

### SUMMARY OF THE INVENTION

A method for manufacturing a SiC substrate of the present invention includes a polishing step of polishing a plate-shaped SiC material by moving a polishing pad, obtained by applying an abrasive to a pad, relative to the SiC material in a state where the polishing pad is in contact with the SiC material. The abrasive contains colloidal silica and a dispersion medium in which the colloidal silica is dispersed and the abrasive has a pH of 4 to 9.

It should be noted that in this specification “SiC material” refers to a SiC substrate prior to being subjected to a polishing process.

Also, “moving a polishing pad relative to the SiC material” refers to moving at least one of the polishing pad and the SiC material relative to the other and includes cases in which only one of the polishing pad and the SiC material is moved, for example. Also, the above-mentioned “relative movement” includes not only movement through which a spatial position is changed but also movement, such as rotation, through which a spatial position is not changed.

### BRIEF DESCRIPTION OF THE DRAWINGS

FIG. 1A is a schematic process diagram showing an example of a method for manufacturing a SiC substrate of the present invention.

FIG. 1B is a conceptual diagram of an abrasive that is used in the example of the method for manufacturing a SiC substrate of the present invention.

FIG. 2 is a schematic process diagram showing another example of the method for manufacturing a SiC substrate of the present invention.

FIG. 3 is a schematic process diagram showing still another example of the method for manufacturing a SiC substrate of the present invention.

### DETAILED DESCRIPTION OF THE INVENTION

In the present invention, an abrasive that contains colloidal silica and a dispersion medium in which the colloidal silica is dispersed and that has a pH of 4 to 9 is used to polish a SiC material, so that it is possible to suppress processing damage and cracks while alleviating the burden on a polishing device or on the environment. Consequently, a SiC substrate with a small surface roughness and high reliability can be manufactured.

It should be noted that in this specification “surface roughness” refers to an average value of values (arithmetic mean deviation of the profile) that are measured at a plurality of points with a measurement instrument such as an optical interference type surface roughness measuring apparatus. The smaller the “surface roughness,” the more uniform and the smoother the polished surface of a SiC material that has been polished.

An example of the method for manufacturing a SiC substrate of the present invention will be described in detail with reference to the drawings.

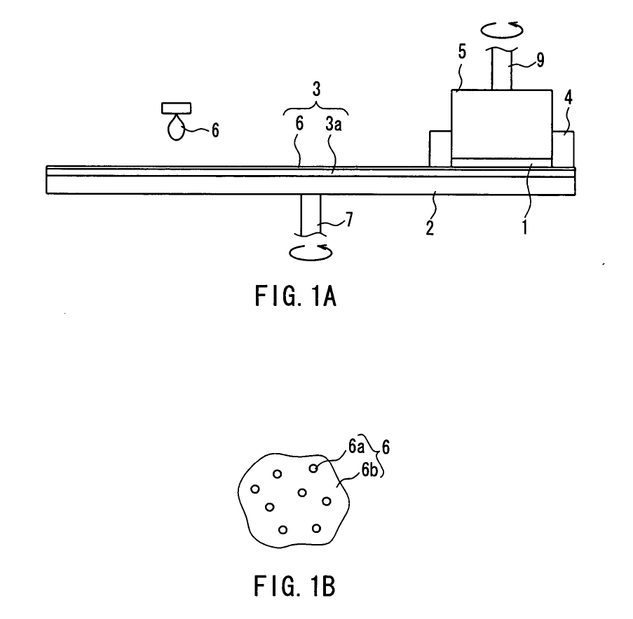

As shown in FIG. 1A, a pad 3a is fixed to a rotary table (lower plate) 2. A plate-shaped SiC material 1 is fixed to a weight 5 and the SiC material 1 is pressed onto the pad 3a by the load of the weight 5. That is, the method for manufacturing a SiC substrate shown in FIG. 1A adopts a method of carrying out polishing using the load of a weight, for example. The SiC material 1 is disk-shaped, for example. The weight 5 is provided with a guide 4 for holding the SiC material 1 in a predetermined position so that the SiC material 1 does not deviate from the predetermined position.

When the rotary table 2 is rotated around a rotation shaft 7 in the arrow direction while an abrasive 6 is dripped intermittently onto the pad 3a, a polishing pad 3, obtained by applying the abrasive 6 to the pad 3a, comes into contact with the SiC material 1. When the weight 5 is simultaneously rotated around a rotation shaft 9 in the arrow direction, polishing of the SiC material 1 by the polishing pad 3 is started. In the example shown in FIG. 1A, the rotary table 2 and the weight 5 are rotated in the same direction. However, it is possible that the rotary table 2 and the weight 5 are rotated in opposite directions, and it is also possible that only one of the rotary table 2 and the weight 5 is rotated, as long as the polishing pad 3 is moved relative to the SiC material 1.

As shown in FIG. 1B, the abrasive 6 contains colloidal silica 6a and a dispersion medium 6b in which the colloidal silica 6a is dispersed. It is preferable that the abrasive 6 contains colloidal silica 6a in the proportion of 50 wt % or less. The reason for this is that if the colloidal silica 6a content of the abrasive 6 is too high, then the abrasive 6 becomes unstable so that gelling of the abrasive 6 occurs during polishing of the surface of the SiC material 1, for example.

It should be noted that there is no particular limitation regarding the lower limit of the percentage by weight of colloidal silica 6a, but usually 0.1 wt % or more is preferable because the polishing efficiency deteriorates if the content of colloidal silica 6a is too low.

For example, when the rotary table 2 is rotated at a rotational velocity of 40 rpm and when the rotary table 2 has a diameter of 200 mm, then the abrasive 6 is dripped onto the pad 3a at a rate of 0.005 ml or more in a period of 10 seconds at room temperature (about 23° C.). Also, when the rotary table 2 is rotated at a rotational velocity of 40 rpm and when the rotary table 2 has a diameter of 300 mm, for example, then the abrasive 6 is dripped at a rate of 0.005 ml or more in a period of 5 seconds at room temperature (about 23° C.). In this way, the surface of the pad 3a is kept from drying, and the surface of the pad 3a can be kept covered with the abrasive 6. It should be noted that when the rotary table 2 has a diameter of 300 mm or less, the rotation speed of the rotary table 2 is preferably 10 rpm to 100 rpm in light of the polishing speed and the consumption of the abrasive 6.

It is preferable that the pad 3a that is used in the method for manufacturing a SiC substrate of this embodiment contains a porous material. When the abrasive 6 is dripped and applied onto a porous material, colloidal silica 6a penetrates into the pores of the porous material. The colloidal silica 6a that has penetrated into the pores is fixed to the porous material by a hydration layer enclosing the colloidal silica 6a. Thus, the colloidal silica 6a that has been dripped onto the pad 3a acts as if it were a fixed abrasive grain. Therefore, when the polishing pad 3 contains a porous material, the polishing speed can be increased and a SiC substrate with a small surface roughness can be obtained.

It is preferable that the pad 3a contains a porous material that includes at least one material selected from the group consisting of synthetic fibers, glass fibers, natural fibers, and resins, for example. In particular, it is preferable that the pad 3a contains a porous material that includes at least one material selected from the group consisting of synthetic fibers, natural fibers, and resins. The reason for this is that when using the pad 3a that contains a soft material as described above, the damage to the SiC material 1 can be suppressed.

There is no particular limitation regarding the average particle size of colloidal silica 6a, but 200 nm or less is preferable. The reason for this is that if the average particle size is too large, then it becomes difficult to disperse colloidal silica 6a in the dispersion medium 6b in a stable state, and thus a problem such as a change in the average particle size occurs during polishing. Another reason is that if the average particle size is too large, then it becomes difficult for colloidal silica 6a to be fixed in the pores of the pad 3a, and thus the precision of polishing is decreased (and the surface roughness of a SiC substrate is increased). Therefore, an abrasive 6 that contains colloidal silica 6a having an average particle size of more than 200 nm generally is not suitable, particularly for the final polishing step in which it is required to reduce the surface roughness even more.

As the dispersion medium 6b that is contained in the abrasive 6, pure water and the like or pure water and the like to which a pH adjuster such as ammonia, citric acid, or potassium hydroxide is added can be used, for example.

In order to polish the SiC material 1 at a speed that is sufficient in practice while alleviating the burden on the pad 3a, for example, of the polishing apparatus or on the environment, the abrasive 6 is required to have a pH of 4 to 9, but it is preferable that the abrasive 6 has a pH of 6 to 8. This is because the SiC material 1 can be polished at a higher speed (with greater efficiency) while alleviating the burden on the pad 3a, for example, of the polishing apparatus or on the environment.

It is preferable that the pressure under which the SiC material 1 is pressed onto the polishing pad 3 is 294 kPa or less. In the example shown in FIG. 1A, the SiC material 1 is pressed onto the polishing pad 3 with the weight 5, so that the above-mentioned pressure is a pressure that is applied to the SiC material 1 by the weight 5.

When the SiC material 1 is pressed onto the polishing pad 3 with the weight 5 that is placed on the SiC material 1, it is particularly preferable that the pressure under which the SiC material 1 is pressed onto the polishing pad 3 is 44 kPa or less. When the pressure is high, the polishing speed increases, but the surface roughness of a SiC substrate increases.

The following is a description of the reason why an excessive pressure under which the SiC material 1 is pressed onto the polishing pad 3 makes it impossible to obtain a SiC substrate having a small surface roughness, when the SiC material 1 is pressed onto the polishing pad 3 with the weight 5.

In order to increase the pressure under which the SiC material 1 is pressed onto the polishing pad 3, it is necessary to increase the size of the weight 5. However, if the size of the weight 5 is increased, then the weight 5 loses its balance during rotation, so that it becomes impossible to process the SiC material 1 uniformly and smoothly using the weight 5. For example, when a SiC material 1 having a diameter of 2 inches (about 50 mm) is pressed onto the polishing pad 3 using the weight 5 in the form of a cylinder, the diameter of the face of the weight 5 that is in contact with the SiC material 1 is set to 2 inches (about 50 mm), for example. When the weight 5 is made of iron, for example, the height of the weight 5 is about 100 mm in order to apply a pressure of 7.9 kPa to the SiC material 1, and the height of the weight 5 is about 600 mm in order to apply a pressure of 50 kPa to the SiC material 1.

In this way, the height of the weight 5 increases as the pressure under which the SiC material 1 is pressed onto the polishing pad 3 is increased. If the height of the weight 5 increases, then the weight 5 vibrates significantly during polishing of the SiC material 1, causing unevenness in the pressure that is applied to the SiC material 1. Consequently, the surface roughness increases in the face of the polished SiC material 1 (SiC substrate). However, if the pressure under which the SiC material 1 is pressed onto the polishing pad 3 is 44 kPa or less, then a SiC substrate having a small surface roughness of 0.5 nm or less, for example, can be obtained.

It should be noted that the surface roughness of the polished SiC material 1 (SiC substrate) can be made smaller as the pressure under which the SiC material 1 is pressed onto the polishing pad 3 is decreased, but the polishing speed is decreased (the polishing efficiency deteriorates), and thus it is preferable in practice that the pressure under which the SiC material 1 is pressed onto the polishing pad 3 is at least 4.9 kPa.

The above-described pressure may be changed according to the state of the surface of the SiC material 1 to be polished. For example, it is possible that in the step of polishing the surface of the SiC material 1, polishing of the surface of the SiC material 1 is performed a plurality of times, and only for the last time of the plurality of times in which it is required to perform polishing such that the surface roughness is decreased even more, the SiC material 1 is polished while the surface of the SiC material 1 is pressed onto the polishing pad 3 under a pressure of 44 kPa or less. It is also possible that, for example, in the step of polishing the surface of the SiC material 1, polishing of the surface of the SiC material 1 is performed a plurality of times, and a paste containing diamond abrasive grains is used to polish the SiC material 1 for the first time of the plurality of times and the above-described abrasive 6 is used to polish the SiC material 1 for the last time. Moreover, it is also possible to change the average particle size of colloidal silica 6a every time polishing is performed.

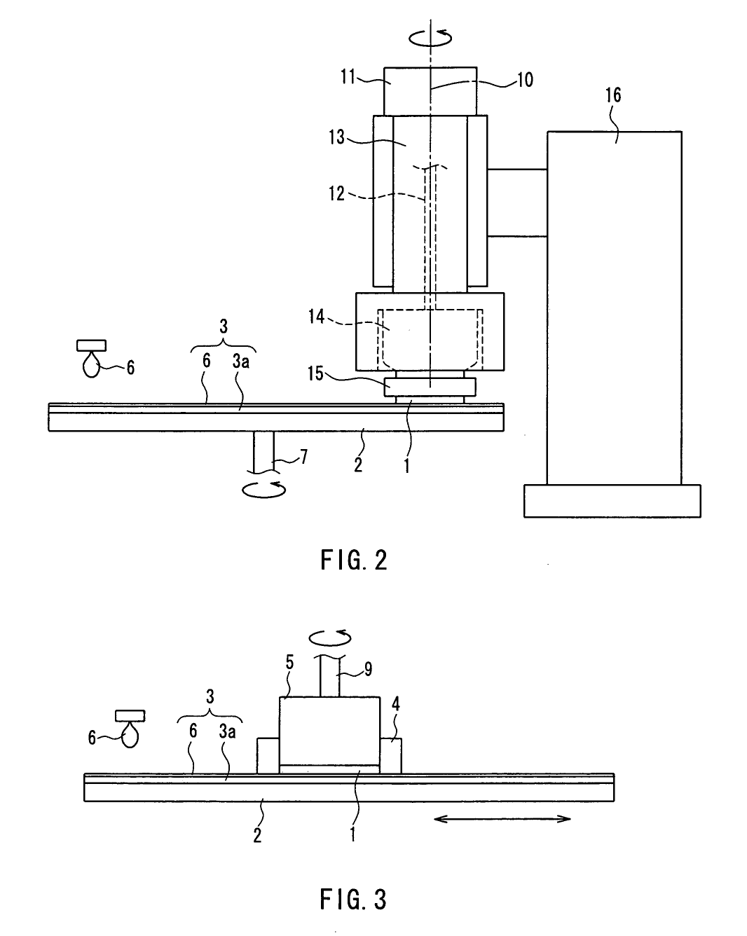

It should be noted that in the example shown in FIG. 1A, the SiC material 1 is pressed onto the polishing pad 3 by the load of the weight 5, but the method for pressing the SiC material 1 onto the polishing pad 3 is not limited to this. For example, it is possible to use a pressing apparatus as shown in FIG. 2 to press the SiC material 1 onto the polishing pad 3. This pressing apparatus includes a pressing head 15 and a pressing mechanism, for example. The pressing head 15 is used in a position that is on the side of the SiC material 1 that is opposite to the polishing pad 3 side, and the pressing mechanism is capable of pushing the pressing head 15 in the direction in which the SiC material 1 is pressed onto the polishing pad 3. The pressing mechanism is capable of pushing the pressing head 15 using at least one type of pressure selected from the group consisting of pressure by spring elasticity, hydraulic pressure, and air pressure, for example.

The pressing apparatus shown in FIG. 2 is a mechanism for pressing the surface of the SiC material 1 onto the polishing pad 3 by air pressure. The pressing apparatus shown in FIG. 2 includes a drive motor 11, an air supply channel 12, a rotation shaft 13, an air bag 14, the pressing head 15, and a head support stand 16, for example. The rotation shaft 13 rotates around an axis 10 in accordance with rotation of the drive motor 11. The pressing mechanism of the pressing apparatus shown in FIG. 2 includes the air supply channel 12 and the air bag 14. The air bag 14 has a structure in which the inner surface thereof is covered with a soft material such as rubber. The pressing head 15 is attached directly to the bottom face of the air bag 14. Thus, when a pressure is applied to the inside of the air bag 14, the pressing head 15 that is in contact with the bottom face of the air bag 14 is pushed downward. Since the inside of the air bag 14 is pressurized by air, the pressure is applied equally to the entire inner surface of the air bag 14. If the area of contact between the air bag 14 and the pressing head 15 is made equivalent to or larger than the area of the face of the SiC material 1 on the pressing head 15 side, then the pressure that is applied to the SiC material 1 can be made uniform. Moreover, since the pressing apparatus is provided with the head support stand 16, the entire pressing apparatus is prevented from moving when the SiC material 1 is pressed onto the polishing pad 3, and thus the SiC material 1 can be processed uniformly and smoothly.

It should be noted that the pressing apparatus shown in FIG. 2 is provided with the drive motor 11, but the pressing apparatus does not have to be provided with the drive motor 11 because it is not necessarily required to rotate the pressing head 15.

When the SiC material 1 is pressed onto the polishing pad 3 by pressing the pressing head 15 onto the SiC material 1 by air pressure and the like, as in the case where the pressing apparatus shown in FIG. 2 is used, a pressure can be applied to the SiC material 1 uniformly even when polishing is performed using a higher pressure (for example, 70 kPa) than in the case where the SiC material 1 is pressed onto the polishing pad 3 by the load of the weight 5 as in the example shown in FIG. 1A. Accordingly, a SiC substrate having a small surface roughness can be obtained even more rapidly.

Also in the case where the SiC material 1 is pressed onto the polishing pad 3 using the pressing apparatus as shown in FIG. 2, it is preferable in practice that the pressure under which the SiC material 1 is pressed onto the polishing pad 3 is at least 4.9 kPa.

The pressure under which the SiC material 1 is pressed onto the polishing pad 3 using the pressing apparatus may be changed according to the state of the surface of the SiC material 1 to be polished. For example, it is possible that in the step of polishing the surface of the SiC material 1, polishing of the surface of the SiC material 1 is performed a plurality of times, and only for the last time of the plurality of times in which it is required to perform polishing with higher precision, the SiC material 1 is polished while the surface of the SiC material 1 is pressed onto the polishing pad 3 under a pressure of 70 kPa or less. It is also possible that, for example, in the step of polishing the surface of the SiC material 1, polishing of the surface of the SiC material 1 is performed a plurality of times, and a paste containing diamond abrasive grains is used to polish the SiC material 1 for the first time of the plurality of times and the above-described abrasive 6 is used to polish the SiC material 1 for the last time. Moreover, it is also possible that the average particle size of colloidal silica 6a is changed every time polishing is performed.

In the examples shown in FIGS. 1A and 2, the SiC material 1 is polished by rotating the rotary table (lower plate) 2 and the SiC material 1 in the arrow direction. However, it is also possible to move the polishing pad 3 relative to the SiC material 1 by moving the lower plate 2 back and forth in the arrow direction, as shown in FIG. 3.

The diameter of the obtained SiC substrate is usually 50 mm to 75 mm.

Hereinafter, an example of the method for manufacturing a SiC substrate of the present invention will be described in more detail. It should be noted that the average particle size of colloidal silica was obtained by conversion from the value of the surface area of colloidal silica that was measured using a surface area measuring apparatus (manufactured by YUASA-IONICS CO., LTD., Multisorb). The surface profile of the SiC material 1 was measured using an optical interference type surface roughness measuring apparatus (manufactured by Zygo Corporation, New View 5032). The surface roughness of the SiC substrate was measured in the following manner.

[Surface Roughness]

The arithmetic mean deviation of the profile was measured at the center of the SiC substrate and four points (at intervals of 90 degrees) that are positioned in the region within 5 mm from the perimeter of the SiC substrate using the optical interference type surface roughness measuring apparatus (manufactured by Zygo Corporation, New View 5032), and the average (surface roughness) of the values at these five points was obtained. It should be noted that the smaller the surface roughness that was thus calculated, the more uniform and the smoother the polished surface of the SiC material 1 that has been polished.

### EXAMPLES 1 to 6

First, abrasives 6 having a pH of 4, 5, 6, 7, 8, and 9 were produced by mixing 5.3 wt % of colloidal silica (average particle size: 15 nm) with 94.7 wt % of a dispersion medium containing pure water and a pH adjuster. Citric acid was used as the pH adjuster in order to adjust pH to more acidic levels, and potassium hydroxide was used as the pH adjuster in order to adjust pH to more alkaline levels. The pH adjuster was added after mixing of colloidal silica with pure water.

Then, the rotary table 2 (diameter of 200 mm) and the weight 5 were rotated around the rotation shaft 7 and the rotation shaft 9, respectively, in the arrow direction with the abrasive 6 dripped intermittently onto the pad 3a at room temperature (23° C.) to polish a SiC material 1 (diameter of 50 mm) having a surface roughness of 1.0 nm until the surface roughness reached 0.7 nm. The abrasive 6 was dripped onto the pad 3a such that it was applied to the pad 3a at a rate of 0.01 ml in a period of 10 seconds.

It should be noted that a commercially available porous material made of polyurethane (manufactured by Rodel nitta company, Product name:SUBA400) was used for the pad 3a. The rotary table 2 was rotated at a velocity of 40 rpm. The SiC material 1 was rotated at a velocity of 40 rpm. The pressure that was applied to the SiC material 1 by the weight 5 was set to 7.9 kPa (see FIG. 1).

### COMPARATIVE EXAMPLE 1

A SiC material (diameter 50 mm) having a surface roughness of 1.0 nm was polished until the surface roughness reached 0.7 nm in the same manner as in Examples 1 to 6 except that a slurry containing 0.2 wt % of diamond abrasive grains (average grain size: 125 nm) and 99.8 wt % of water was used instead of the abrasives 6 that were produced in Examples 1 to 6. The slurry was dripped onto the pad 3a such that it was applied to the pad 3a at a rate of 0.01 ml in a period of 10 seconds.

### Comparative Examples 2 to 4

First, abrasives having a pH of 3, 10, and 11 were produced by mixing 5.3 wt % of colloidal silica (average particle size: 15 nm) with 94.7 wt % of a dispersion medium containing pure water and a pH adjuster. Then, SiC materials (diameter of 50 mm) having a surface roughness of 1.0 nm were polished until the surface roughness reached 0.7 nm in the same manner as in Examples 1 to 6 except that these abrasives were used. Citric acid was used in order to adjust pH to more acidic levels, and potassium hydroxide was used in order to adjust pH to more alkaline levels.

Table 1 shows the pH dependence of the polishing speed. In Table 1, a polishing speed that is as high as or higher than the polishing speed in the case (Comparative Example 1) where the slurry containing diamond abrasive grains was used to perform polishing is indicated by “high.” Also, a polishing speed that is a little lower than the polishing speed in the case (Comparative Example 1) where the above-described slurry was used to perform polishing but that is a sufficient speed in practice is indicated by “medium,” and a polishing speed that is an order of magnitude lower than the polishing speed in the case where the above-described slurry was used to perform polishing is indicated by “low.”

Moreover, data on the surface profile of the SiC substrates were obtained by scanning vertically an area of 100 μm×100 μm on each polished SiC material 1 (SiC substrate) with the optical interference type surface roughness measuring apparatus. From the obtained data, it was examined whether or not a straight line or a curved line was present. When a straight line or a curved line was present, it was determined that there was a processing damage, and when they were not present, it was determined that there were no processing damages. The results were shown in Table 1.

TABLE 1

| | | | presence or absence of |
|---|---|---|---|
| | PH | polishing speed | processing damage |
| Example 1 | 4 | medium | not present |
| Example 2 | 5 | medium | not present |
| Example 3 | 6 | high | not present |
| Example 4 | 7 | high | not present |
| Example 5 | 8 | high | not present |
| Example 6 | 9 | medium | not present |
| Comparative Example 1 | — | — | present |
| Comparative Example 2 | 3 | low | not present |
| Comparative Example 3 | 10 | medium | not present |
| Comparative Example 4 | 11 | low | not present |

As shown in Table 1, it was confirmed that with the abrasives 6 having a pH of 4 to 10, the SiC materials 1 could be polished at a speed that is sufficient in practice even when the abrasives 6 were neutral or weakly acidic. In particular, it was found that in the case where the abrasives 6 having a pH of 6 to 8, that is, the abrasives 6 having a pH that was adjusted to an almost neutral level, were used, the polishing speed was as high as or higher than the polishing speed in the case where the slurry containing diamond abrasive grains was used to perform polishing.

Moreover, the shape of the pad 3a after use was observed visually and using a microscope, and it was found that the pad 3a was seriously damaged in the cases where the abrasives having a pH of 10 and 11 were used. Also, there was no discoloration in the pad 3a in the cases where the abrasives having a pH that was adjusted to an almost neutral level were used, whereas the pad 3a was clearly discolored in the cases where the abrasives having a pH of 10 and 11 were used.

Processing damages were not found in any of the SiC substrates in Examples 1 to 6 and the SiC substrates in Comparative Examples 2 to 4.

As described above, it could be confirmed that if an abrasive having a pH of 4 to 9 is used, then a SiC substrate with high reliability can be manufactured at a speed that is sufficient in practice while alleviating the burden on the pad 3a, for example, of the polishing apparatus or on the environment. In particular, it could be confirmed that if an abrasive having a pH of 6 to 8 is used, then a SiC substrate with high reliability can be manufactured at a higher speed while alleviating the burden on the pad 3a, for example, of the polishing apparatus or on the environment.

### EXAMPLES 7 to 10

First, an abrasive 6 (pH 7) was produced by mixing 5.3 wt % of colloidal silica (average particle size: 15 nm) with 94.7 wt % of a dispersion medium containing pure water and a pH adjuster. Citric acid was used as the pH adjuster. Then, the rotary table 2 (diameter of 200 mm) and the weight 5 were rotated around the rotation shaft 7 and the rotation shaft 9, respectively, in the arrow direction with the abrasive 6 intermittently dripped onto the pad 3a at room temperature (23° C.) to polish a SiC material 1 (diameter of 50 mm) having a surface roughness of 0.7 nm. The abrasive 6 was dripped onto the pad 3a such that it was applied to the pad 3a at a rate of 0.01 ml in a period of 10 seconds.

It should be noted that a commercially available porous material made of polyurethane (manufactured by Rodel nitta company, Product name:SUBA400) was used for the pad 3a. The rotary table 2 was rotated at a velocity of 40 rpm. The SiC material 1 was rotated at a velocity of 40 rpm. The pressure that was applied to the SiC material 1 by the weight 5 was set to 7.9 kPa, 25 kPa, 44 kPa, and 49 kPa.

TABLE 2

| | pressure [kPa] | surface roughness [nm] |
|---|---|---|
| Example 7 | 7.9 | 0.2 |
| Example 8 | 25 | 0.4 |
| Example 9 | 44 | 0.5 |
| Example 10 | 49 | 0.6 |

As shown in Table 2, when the pressure under which the SiC material 1 was pressed onto the polishing pad 3 was set to 44 kPa or less, a SiC substrate having a surface roughness of 0.5 nm or less could be obtained. On the other hand, when the pressure under which the SiC material 1 was pressed onto the polishing pad 3 was higher than 44 kPa, it was impossible to obtain a SiC substrate having a surface roughness of 0.5 nm or less.

### EXAMPLES 11 to 14

In Examples 11 to 14, the pressing apparatus shown in FIG. 2 was used. First, an abrasive 6 (pH 7) was produced by mixing 40 wt % of colloidal silica (average particle size: 40 nm) with 60 wt % of a dispersion medium containing pure water and a pH adjuster. Citric acid was used as the pH adjuster. Then, the rotary table 2 (diameter of 600 mm) was rotated around the rotation shaft 7 in the arrow direction with the abrasive 6 intermittently dripped onto the pad 3a to polish a SiC material 1 (diameter of 50 mm) having a surface roughness of 0.7 nm. The abrasive 6 was dripped onto the pad 3a such that it was applied to the pad 3a at a rate of 0.5 ml in a period of 10 seconds.

It should be noted that a commercially available porous material made of polyurethane (manufactured by Rodel nitta company, Product name:SUBA400) was used for the pad 3a. The rotary table 2 was rotated at a velocity of 40 rpm. The SiC material 1 was rotated at a velocity of 40 rpm. The pressure under which the SiC material 1 was pressed onto the polishing pad 3 by the pressing head 15 that was energized by air pressure was set to 34 kPa, 54 kPa, 70 kPa, and 98 kPa.

TABLE 3

| | | surface roughness | ratio of processing |
|---|---|---|---|
| | pressure [kPa] | [nm] | speed |
| Example 7 | 7.9 | 0.2 | 1 |
| Example 11 | 34 | 0.2 | 40 |
| Example 12 | 54 | 0.2 | 100 |
| Example 13 | 70 | 0.4 | 100 |
| Example 14 | 98 | 0.4 | 100 |

As shown in Table 3, when the pressure under which the SiC material 1 was pressed onto the polishing pad 3 was set to 54 kPa or less, a SiC substrate having a surface roughness of 0.2 nm could be obtained at a speed about 100 times higher than in Example 7. Moreover, also when the pressure under which the SiC material 1 was pressed onto the polishing pad was 98 kPa, it was possible to obtain a SiC substrate having a surface roughness of 0.4 nm. However, a comparison between Example 13 (70 kPa) and Example 14 (98 kPa) shows that there was no difference in the polishing speed (polishing efficiency) between them. It could be confirmed that the pressure under which the SiC material 1 is pressed onto the polishing pad 3 is preferably not more than 70 kPa considering the fact that the higher the pressure under which the SiC material 1 is pressed onto the polishing pad 3 is, the more likely the SiC material 1 is to be damaged during polishing.

### EXAMPLE 15

First, a SiC material 1 (diameter of 50 mm) having a surface roughness of 1.0 nm was polished using a slurry containing 0.2 wt % of diamond abrasive grains (average grain size: 125 nm) and 99.8 wt % of water until the surface roughness reached 0.65 nm. It should be noted that a commercially available porous material made of polyurethane (manufactured by Rodel nitta company, Product name:SUBA400) was used for the pad 3a. The rotary table 2 (diameter of 200 mm) was rotated at a velocity of 40 rpm, and the SiC material 1 was rotated at a velocity of 40 rpm. The pressure under which the SiC material 1 was pressed onto the polishing pad 3 by the weight 5 was set to 7.9 kPa. The slurry was dripped onto the pad 3a such that it was applied to the pad 3a at a rate of 0.01 ml in a period of 10 seconds. Even when the polishing duration was extended, it was impossible to make the surface roughness smaller than 0.65 nm.

Then, an abrasive 6 (pH=7) was produced by mixing 40 wt % of colloidal silica (average particle size: 40 nm) and 60 wt % of a dispersion medium containing pure water and a pH adjuster. Citric acid was used as the pH adjuster. Next, the rotary table 2 (diameter of 600 mm) and the pressing head 15 of the pressing apparatus shown in FIG. 2 were rotated around the rotation shaft 7 and the rotation shaft 13, respectively, in the arrow direction with the abrasive 6 intermittently dripped onto the pad 3a at room temperature (23° C.) to polish the SiC material 1 that had already been processed to a surface roughness of 0.65 nm using the slurry containing diamond abrasive grains.

The abrasive 6 was dripped onto the pad 3a such that it was applied to the pad 3a at a rate of 0.5 ml in a period of 10 seconds.

It should be noted that a commercially available porous material made of polyurethane (manufactured by Rodel nitta company, Product name:SUBA400) was used for the pad 3a. The rotary table 2 was rotated at a velocity of 40 rpm, and the SiC material 1 was rotated at a velocity of 40 rpm. The pressure under which the SiC material 1 was pressed onto the polishing pad 3 by the pressing head 15 that was energized by air pressure was set to 54 kPa. In this way, a SiC substrate having a surface roughness of 0.2 nm could be obtained.

The invention may be embodied in other specific forms without departing from the spirit or essential characteristics thereof. The embodiments disclosed in this application are to be considered in all respects as illustrative and not restrictive, the scope of the invention being indicated by the appended claims rather than by the foregoing description. All changes that come within the meaning and range of equivalency of the claims are intended to be embraced therein.

1. A method for manufacturing a SiC substrate comprising:
a polishing step of polishing a plate-shaped SiC material by moving a polishing pad, obtained by applying an abrasive to a pad, relative to the SiC material in a state where the polishing pad is in contact with the SiC material,
wherein the abrasive contains colloidal silica and a dispersion medium in which the colloidal silica is dispersed and the abrasive has a pH of 4 to 9.

2. The method for manufacturing a SiC substrate according to claim 1, wherein the abrasive contains the colloidal silica in a proportion of 50 wt % or less.

3. The method for manufacturing a SiC substrate according to claim 1, wherein the abrasive has a pH of 6 to 8.

4. The method for manufacturing a SiC substrate according to claim 1, wherein the pad is a porous material containing at least one material selected from the group consisting of synthetic fibers, glass fibers, natural fibers, and resins.

5. The method for manufacturing a SiC substrate according to claim 1, wherein in the polishing step, the SiC material is polished while the SiC material is pressed onto the polishing pad under a pressure of 294 kPa or less.

6. The method for manufacturing a SiC substrate according to claim 1, wherein in the polishing step, the SiC material is polished while the SiC material is pressed onto the polishing pad under a pressure of 44 kPa or less with a weight that is placed on the SiC material.

7. The method for manufacturing a SiC substrate according to claim 1, wherein in the polishing step, polishing of the SiC material is performed a plurality of times, and for the last time of the plurality of times, the SiC material is polished while the SiC material is pressed onto the polishing pad under a pressure of 44 kPa or less with a weight that is placed on the SiC material.

8. The method for manufacturing a SiC substrate according to claim 1, wherein the SiC material is polished while the SiC material is pressed onto the polishing pad under a pressure of 70 kPa or less by a pressing apparatus.

9. The method for manufacturing a SiC substrate according to claim 8, wherein the pressing apparatus comprises a pressing head that is used in a position that is on the side of the SiC material that is opposite to the polishing pad side and a pressing mechanism for pushing the pressing head in the direction in which the SiC material is pressed onto the polishing pad.

10. The method for manufacturing a SiC substrate according to claim 9, wherein the pressing mechanism pushes the pressing head using at least one type of pressure selected from the group consisting of pressure by spring elasticity, hydraulic pressure, and air pressure.

11. The method for manufacturing a SiC substrate according to claim 1, wherein in the polishing step, polishing of the SiC material is performed a plurality of times, and for the last time of the plurality of times, the SiC material is polished while the SiC material is pressed onto the polishing pad under a pressure of 70 kPa or less by a pressing apparatus.

12. The method for manufacturing a SiC substrate according to claim 11, wherein the pressing apparatus comprises a pressing head that is used in a position that is on the side of the SiC material that is opposite to the polishing pad side and a pressing mechanism for pushing the pressing head in the direction in which the SiC material is pressed onto the polishing pad.

13. The method for manufacturing a SiC substrate according to claim 12, wherein the pressing mechanism pushes the pressing head using at least one type of pressure selected from the group consisting of pressure by spring elasticity, hydraulic pressure, and air pressure.
